(19) United States
(12) Patent Application Publication
(10) Pub. No.: US 2015/0179394 A1
(43) Pub. Date: Jun. 25, 2015

(54) Charged Particle Device

(71) Applicant: Hitachi High-Technologies Corporation, Minato-ku, Tokyo (JP)

(72) Inventors: Tsutomu Saito, Tokyo (JP); Kenji Aoki, Tokyo (JP)

(73) Assignee: Hitachi High-Technologies Corporation, Minato-ku, Tokyo (JP)

(21) Appl. No.: 14/404,115

(22) PCT Filed: Apr. 22, 2013
(86) PCT No.: PCT/JP2013/061706

§ 371 Date: Nov. 26, 2014

(30) Foreign Application Priority Data
May 31, 2012 (JP) 2012-123882

(51) Int. Cl. H01J 37/10; H01J 37/26

(52) U.S. Cl. CPC H01J 37/10; H01J 37/26; H01J 2237/103

(57) ABSTRACT

A preferred aim of the present invention is to provide a charged particle beam device having a high differential exhaust performance while maintaining a large dynamic range of an irradiation current by effectively arranging an aperture for differential pumping (111) and an objective final aperture (110). The present invention has features that a lens barrel including therein an optical system of the charged particle beam device (100) includes a first space (106) having a first degree of vacuum and a second space (105) having a degree of vacuum higher than the first degree of vacuum, and that the objective final aperture (110) is arranged in the second space (105).

### TECHNICAL FIELD

The Present invention relates to a charged particle beam device, and, more particularly, relates to a charged particle beam device that detects a signal received from a sample due to the irradiation with a charged particle beam and takes an image of the sample.

### BACKGROUND ART

In a charged particle beam device such as a scanning electron microscope, it is desired that a beam current amount of a charged particle beam with which a sample is irradiated is variable. As a technique making the beam current amount variable, Patent Document 1 is cited. This patent publication describes a point that an outer peripheral part of a probe current is removed by using an aperture electrode arranged in a lens barrel of the scanning electron microscope.

In addition, Patent Document 2 describes a point that a probe current is adjusted by adjusting a distance between a crossover point made by a convergent lens and an objective aperture.

### PRIOR ART DOCUMENTS

### Patent Documents

Patent Document 1: International Publication No. WO/2010/146833

Patent Document 2: Japanese Patent Application Laid-Open Publication No. 2010-282977

### SUMMARY OF THE INVENTION

### Problems to be Solved by the Invention

As described in Patent Documents 1 and 2, in order to apply a charged particle beam to a minute region, a particle beam diameter and a particle beam amount are made small by using an objective final aperture. In order to secure a dynamic range so as to achieve a necessary particle beam diameter and particle beam amount, it is required to have a hole diameter of the objective final aperture so as to be a certain degree of a size such as about 10 μm to 200 μm.

In order to generate a stable charged particle from an emitter of the charged particle, an extreme high vacuum (e.g., 10⁻⁷ Pa order) is required for an atmosphere in a periphery of the emitter of the charged particle. On the other hand, a lower vacuum (e.g., 100 Pa order) than that of the atmosphere in the periphery of the emitter of the charged particle is required for an object on which a charged particle is applied in some cases in order to avoid charging up generated by the application of the charged particle. Therefore, a high differential pumping performance (e.g., 10⁴ to 10¹⁰ times) is required in a portion between the emitter of the charged particle and the object. This differential pumping is achieved by an aperture for differential pumping provided in a charged particle optical system.

The smaller the diameter of the aperture for differential pumping is, the larger the differential pumping performance is. However, when the diameter of the aperture for differential pumping is too small, the charged particle beam which is desired to reach the sample is partially blocked, or the charged particle beam is totally blocked in the worst case, and therefore, axis adjustment cannot be performed.

Then, a preferred aim of the present invention is to provide a charged particle device having a high differential pumping performance while maintaining a large dynamic range of an irradiation current by effectively arranging the aperture for differential pumping and the objective final aperture.

### Means for Solving the Problems

In order to solve the above-described problems, for example, configurations described in the claims are adopted.

The present application includes a plurality of means to solve the above-described problems. When an example of the means is cited, a charged particle beam device of the present invention includes a lens barrel including therein: an emitter of charged particle beam which generates a charged particle beam; an condenser lens which can adjust a crossover point of the charged particle beam; an objective final aperture arranged to be closer to a sample side than the condenser lens; and an objective lens which is arranged to be closer to the sample side than the objective final aperture and which converges the charged particle beam on the sample. The charged particle beam device has such features that the lens barrel includes a first space having a first degree of vacuum and a second space having a degree of vacuum higher than the first degree of vacuum, and that the objective final aperture is arranged in the second space.

### Effects of the Invention

According to the present invention, a charged particle device having a high differential pumping performance while maintaining a large dynamic range of an irradiation current can be provided.

Other problems, configurations, and effects than those described above will be apparent from the explanation of the following embodiments.

### BRIEF DESCRIPTIONS OF THE DRAWINGS

FIG. 1 is a diagram illustrating an embodiment of a charged particle device of a first example;

FIG. 2 is a diagram illustrating details of a periphery of an objective final aperture of the charged particle device of the first example;

FIG. 3 is a diagram illustrating an embodiment of a charged particle device of a second example; and

FIG. 4 is a diagram illustrating details of a periphery of an objective final aperture of the charged particle device of the second example.

### DESCRIPTIONS OF THE PREFERRED EMBODIMENTS

In the following examples, a scanning electron microscope (SEM) will be described as an example. However, this is merely an example of the present invention, and therefore, the present invention is not limited to the embodiments described below. The present invention is applicable to a scanning transmission electron microscope (STEM), a transmission electron microscope (TEM), an ion microscope, and the other sample observation devices using a charged particle beam, or a charged particle beam device such as a processing device using a charged particle beam.

First, problems of conventional techniques will be described in detail. As described above, a required degree of vacuum is largely different between the atmosphere in the periphery of the emitter of the charged particle and the atmosphere in a sample chamber. When the sample is practically observed, a sample chamber in which an observation sample is arranged and a chamber for the emitter of the charged particle in which the emitter of the charged particle is arranged are connected by a passage through which a charged particle beam passes, and therefore, an achievement degree of vacuum of the chamber for the emitter of the charged particle largely depends on a vacuumed atmosphere on the sample chamber side. In order to form this differential pressure, the aperture for differential pumping is used. The smaller the diameter of the aperture for differential pumping is, the larger the differential pumping performance is.

On the other hand, in order to apply the charged particle beam to a minute region, a particle beam diameter and particle beam amount are decreased by using the objective final aperture. In order to secure a dynamic range so as to achieve the required particle beam diameter and particle beam amount, a hole diameter of the objective final aperture is required to be a hole diameter of a certain degree of a size such as about 10 μm to 200 μm.

Therefore, depending on a positional relation and a hole diameter relation between the aperture for differential pumping and the objective final aperture, the charged particle beam which is desired to reach the sample obtained after the adjustment by the objective final aperture is partially blocked by the aperture for differential pumping, or the charged particle beam is totally blocked in the worst case, and therefore, axis adjustment cannot be performed.

Therefore, in order to achieve the high differential pumping performance while securing the dynamic range of the irradiation current, it is required to arrange appropriately the positional relation between the aperture for differential pumping and the objective final aperture.

In addition, it is required to design the charged particle optical system so as to be short from merits such as keeping the particle beam diameter to be small in order to make an aberration generated by a lens small, reducing noises influenced by an environment, and reducing materials by reducing a chamber size. Therefore, as for the aperture for differential pumping and objective final aperture, it is desired to reduce a length of the charged particle optical system in addition to the above-described requirements.

Hereinafter, the embodiments of the present invention will be described in examples.

### FIRST EXAMPLE

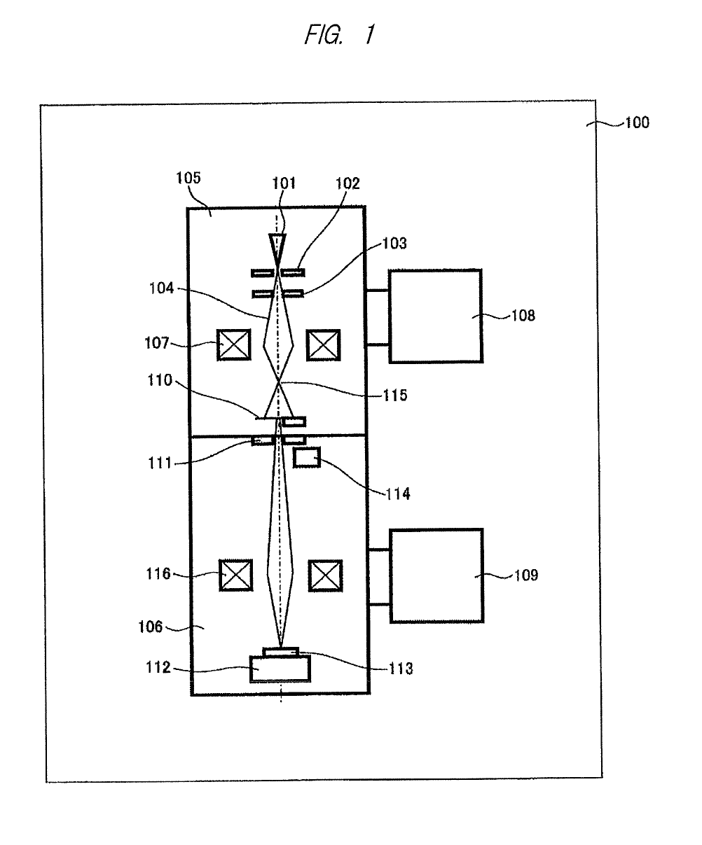

FIG. 1 is an example of a configuration diagram of the charged particle device of the present embodiment.

A charged particle device 100 includes a lens barrel and a stage 112, the lens barrel including a charged particle optical system therein including: an emitter of the charged particle 101; an electrode for the extractor voltage 102; an electrode for the acceleration voltage 103; a condenser lens A107; an objective final aperture 110; an aperture for differential pumping A111; a valve 114; and an objective lens 116, and the stage 112 being for placing an object 113 of observation and analysis thereon. The object 113 is also referred to as a sample. The lens barrel includes therein: a vacuum chamber A105 exhausted by a vacuum exhaust pump A108; and a vacuum chamber B106 exhausted by a vacuum pump B109. In the present specification, the lens barrel is a structure including the charged particle optical system formed from the emitter of the charged particle 101 to the objective lens 116 therein. In FIG. 1, note that the vacuum chamber B106 includes the object 113 and the stage 112. However, a space for placing the object 113 thereon as a sample chamber is distinguished from the lens barrel. The vacuum chamber B106 has an orifice used for the differential exhaust between the objective lens 116 and the object 113, and the charged particle optical system and the sample chamber may have a different degree of vacuum from each other.

A charged particle beam 104 is emitted from the emitter of the charged particle 101 by heat, an electric field of the electrode for the extractor voltage 102, or both effects. Then, a speed of the charged particle beam 104 emitted in one direction is accelerated or reduced by a voltage applied to the electrode 103 for the acceleration voltage, and moves toward the object 113. The charged particle beam 104 which has passed through the electrode 103 for the acceleration voltage is converged by the condenser lens A107 arranged to be closer to the emitter of the charged particle 101 side than the objective final aperture 110. A convergent point at this time is referred to as a crossover point A115. Because the charged particle beam 104 spreads again after converged, a beam diameter of the charged particle beam 104, that is, a current density of the charged particle beam 104 with which the objective final aperture 110 arranged to be closer to the object 113 side than the condenser lens A107 is irradiated can be changed by moving the crossover point A115 on an optical axis by changing an operating state of the condenser lens. Because an outer peripheral part of the beam is blocked and only a part thereof having a predetermined diameter of a beam center portion is made to be passed in the objective final aperture 110, an amount of the beam current of the charged particle beam 104 which passes through the objective final aperture can be adjusted in accordance with the position of the crossover point A115. The objective final aperture of the present example is arranged in the vacuum chamber A105. This objective final aperture desirably has a structure with a changeable hole diameter.

The charged particle beam 104 which has passed through the objective final aperture 110 passes through the aperture for differential pumping A111 and the valve 114, and is converged and applied on the object 113 by the objective lens 116. The object 113 is placed on the stage 112, and can be moved, tilted, and rotated in X and Y directions, and therefore, an appropriate position of the object 113 is irradiated with the converged charged particle beam 104.

Note that the charged particle optical system includes the emitter of the charged particle 101, the condenser lens A107, and the objective final aperture 110, etc. However, in additional to them, the charged particle optical system may include other lens, electrode, deflector and detector, or may include partially different members from the above-described members, and configurations of the charged particle optical system are not limited to them. In the case of the scanning electron microscope, for example, the object is scanned with the electron beam by deflecting the electron beam by the deflector, and secondary electrons and secondary particles such as reflected electrons which are received from the position which is irradiated with the electron beam are detected by the detector, and an image of the object is generated by making a correspondence between this detected signal and the scanned position. The generated image of the object is displayed on a display unit such as a display.

In addition, the charged particle beam device includes a control unit (whose illustration is omitted) which controls each member described above, and each member described above can be brought to a predetermined operating state by a control signal from the control unit. For example, the control unit adjusts the position of the crossover point A115 by controlling an amount of the current flowing through the condenser lens A107. In addition, the control unit may include an input unit for instructing each member of the operating state.

Processing executed in the control unit can be achieved by either method of a hardware and a software program. In the case of the configuration formed of the hardware, the processing can be achieved by integrating a plurality of computing units which execute the processing on a wiring substrate or inside a semiconductor chip or a package. In the case of the configuration formed of the software program, the processing can be achieved by mounting a high-speed general-purpose CPU on a computer and executing a program which executes a desired computing process.

In addition, the control unit, the input unit and the display unit, etc. may be connected with the charged particle beam device 100 through a network for communicating data at any time.

In order to generate the stable charged particle beam 104 from the emitter of the charged particle 101, a high vacuum of 10⁻⁴ to 10⁻⁹ Pa order is required for the atmosphere in the periphery of the emitter of the charged particle 101. The required degree of vacuum depends on a type of the emitter of the charged particle 101. On the other hand, such a high degree of vacuum as the degree of vacuum of the emitter of the charged particle 101 is not required for the sample chamber where the object 113 is placed. In order to maintain the high vacuum in the periphery of the emitter of the charged particle 101, the aperture for differential pumping A111 is placed between the vacuum chamber A105 and the vacuum chamber B106, and the vacuum chamber A105 is vacuum-exhausted by the vacuum pump A108 which has a higher achievement degree of vacuum. Similarly, the vacuum chamber B106 is vacuum-exhausted by the vacuum pump B109 which has a lower achievement degree of vacuum. Owing to an effect of the aperture for differential pumping A111, a differential pressure is generated between the vacuum chamber A105 and the vacuum chamber B106 in accordance with the hole diameter of the aperture for differential pumping A, and the vacuum chamber A105 can be maintained at a higher degree of vacuum. At the time of the observation and analysis, the vacuum chamber A and the vacuum chamber B are in a state in which they are connected through the aperture for differential pumping A. Note that each of the vacuum chamber A105 and the vacuum chamber B106 may be exhausted through two exhaust paths having different exhaust amounts from each other by configuring the vacuum pumps A and B as one vacuum pump.

After achieving an aim such as the observation and analysis of the object 113, it is required to atmospherically expose the vacuum chamber B106 side in order to eject the object 113 from the sample chamber or to replace the object 113 with a different object. Also at this time, the valve 114 is placed between the vacuum chamber A105 and the vacuum chamber B106 so as to close the vacuum chambers from each other in order to maintain a high vacuum on the vacuum chamber A105 side. That is, by making the valve movable, an opening of the aperture for differential pumping A111 is opened when the object is irradiated with the charged particle beam 104 for the observation and analysis etc., and then, the aperture for differential pumping A111 is closed by the valve 114 so as to close the hole of the aperture for differential pumping when the irradiation to the object 113 with the charged particle beam 104 is stopped after the observation and analysis are completed. Although the valve 114 is not always necessary if a load lock mechanism for replacing the object 113 is provided, it is preferred that the vacuum chamber B106 into which the object 113 comes can be atmospherically exposed without depending on the degree of vacuum of the vacuum chamber A105. While the vacuum chamber A105 and the vacuum chamber B106 which are defined here are the minimum vacuum chamber configuration, a charged particle device having a higher differential exhaust performance can be achieved by dividing each of the vacuum chambers into two or more and providing the aperture for differential pumping A111 therebetween.

When pollution due to adhesion of contaminations such as carbon are generated in the objective final aperture 110, the pollution may be a cause of the charging up, or the aperture hole diameter may be narrowed and buried in the worst case. In order to reduce this influence, the objective final aperture 110 is used while heated by a heater in many cases. If the arranged vacuum chamber is atmospherically exposed at the time of the heating of the objective final aperture 110, oxidation is promoted by oxygen in the air so as to pollute the objective final aperture 110.

Conventionally, when the sample is replaced, the sample is placed and used in the sample chamber after passing through a different vacuum chamber once which is called a load lock chamber (not shown) adjacent to the vacuum chamber B, and therefore, it is not assumed that the vacuum of the vacuum chamber B106 is deteriorated. Therefore, a size of the object 113 which can be introduced into the vacuum chamber B106 is limited by the load lock chamber, and besides, the vacuum of the vacuum chamber B106 is also required to be maintained at a certain high degree of the vacuum. On a basis of this condition, the objective final aperture is arranged in the vacuum chamber B. Therefore, in a conventional charged particle beam device, it is required to wait for atmospherically exposing the vacuum chamber until the objective final aperture 110 is cooled.

In the present example, the objective final aperture 110 is arranged inside the vacuum chamber A105. Even when the vacuum chamber B106 is atmospherically exposed, a chamber (vacuum chamber A105) having the objective final aperture 110 is maintained at a high vacuum, and therefore, the vacuum chamber B106 can be atmospherically exposed while heating the objective final aperture. Furthermore, by the objective final aperture 110 arranged to be closer to the emitter of the charged particle 101 side than the valve 114, the vacuum chamber B106 can be atmospherically exposed without depending on the degree of vacuum of the vacuum chamber A105. In this manner, a waiting time for replacing the object 113 can be significantly shortened.

### SECOND EXAMPLE

Next, a relation between the objective final aperture, the aperture for differential pumping and the valve will be described. In the following, explanation for the same portions as those of the first example will be omitted.

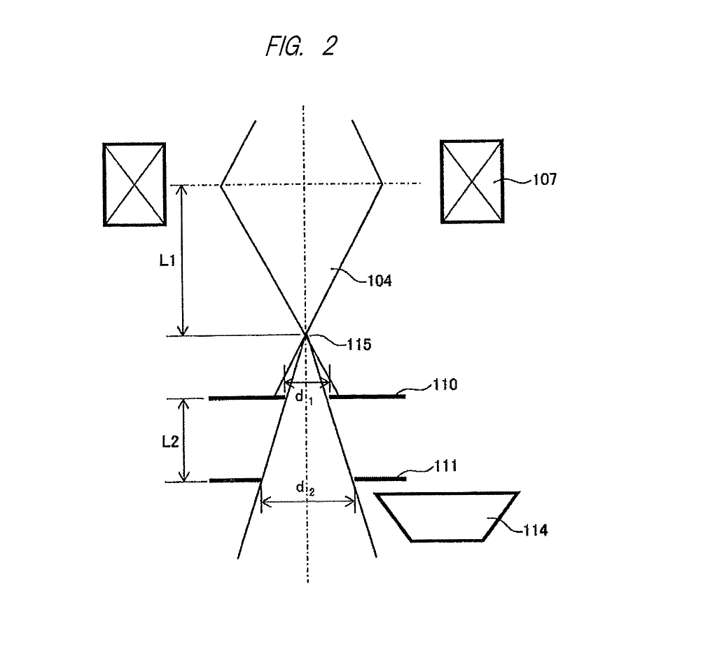

FIG. 2 is an enlarged view of the periphery of the objective final aperture 110 of FIG. 1. By changing a magnitude of a magnetic lens which is generated by the condenser lens A107, the crossover point A115 moves up and down, and an amount of the charged particles which pass through the objective final aperture 110 increases or decreases. The longer a distance L1 from the condenser lens A107 to the crossover point A115 made by the condenser lens A107 is, the larger a range of change in the amount of the charged particles which pass through the objective final aperture 110 is. Therefore, conventionally, the objective final aperture 110 is provided to be closer to the object 113 side than the valve 114.

In order to limit the amount of the charged particles applied on the object 113 by the hole diameter of the objective final aperture 110, the aperture for differential pumping A111 arranged immediately close to the object 113 side has to have such a hole diameter as not blocking the passing charged particle beam 104 under all conditions. Meanwhile, the hole diameter of the aperture for differential pumping A111 determines a differential pressure between the vacuum chamber A105 and the vacuum chamber B106, and therefore, the hole diameter is desirably small as much as possible. The shorter a distance L2 between the objective final aperture 110 and the aperture for differential pumping A111 is, the smaller the hole diameter “d₂” of the aperture for differential pumping A111 can be. Then, in FIG. 2, a structure of the valve 114 is arranged to be closer to the object 113 side than the aperture for differential pumping A111. In addition, in other words from a viewpoint of an arrangement relation among the objective final aperture 110, the aperture for differential pumping A111 and the valve 114, the aperture for differential pumping A111 is arranged to be closer to the object 113 side than the objective final aperture 110, and the valve 114 is arranged to be closer to the object 113 side than the aperture for differential pumping A111. That is, the valve 114, the aperture for differential pumping A111 and the objective final aperture 110 are arranged in this order as an order closer to the object 113. At this time, by arranging the objective final aperture 110 to be close to the valve 114 as much as possible, the range of the change in the amount of the charged particles can be increased.

Owing to this configuration, a distance between the objective final aperture 110 and the aperture for differential pumping A111 can be reduced as much as possible. In consideration of the maximum hole diameter practically required for the objective final aperture 110, a distance “L2” between the objective final aperture 110 and the aperture for differential pumping A111 is desirably shorter than 20 mm.

In addition, in the structure of FIG. 2, the structure of the valve 114 is provided on the high pressure side, and therefore, this structure is difficult to cause a vacuum leakage on the vacuum chamber A105 side on the emitter of the charged particle 101 side when the vacuum chamber B106 located on the object 113 side is atmospherically exposed.

### THIRD EXAMPLE

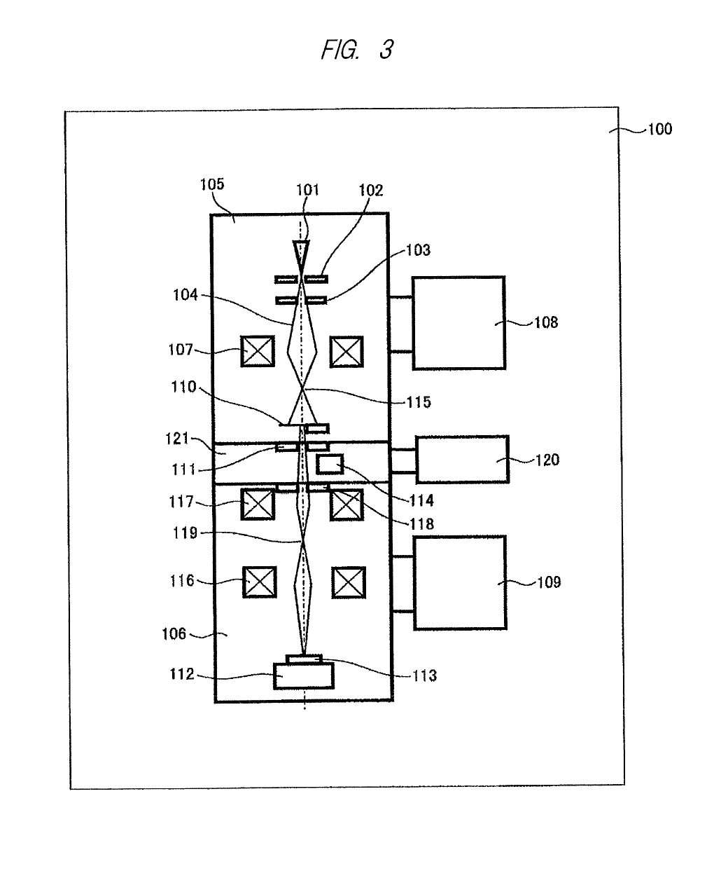

FIG. 3 illustrates a charged particle device 200 obtained by adding, to the configuration of FIG. 1, a condenser lens B117 for controlling an aperture angle of the charged particle beam 104 with which the object 113 is irradiated, an aperture for differential pumping B118 for enhancing a differential exhaust performance, a vacuum chamber C121 partitioned by the aperture for differential pumping A111 and the aperture for differential pumping B118, and a vacuum pump C120 for independently vacuum-exhausting the vacuum chamber C121. By adjusting a position of a crossover point B119 made by the condenser lens B117, an aperture angle of the charged particle beam 104 is controlled. In the following, the explanation of the same portions as those of the first or second example will be omitted.

The aperture for differential pumping B118 is arranged to be closer to the object 113 side than the aperture for differential pumping A111, and the gas in the vacuum chamber C121 is exhausted by the vacuum pump C120, so that the differential exhaust performance from the emitter of the charged particle 101 to the object 113 becomes high, and the degree of vacuum in the periphery of the object 113 can be maintained to be low. The vacuum pump B109 and the vacuum pump C120 are independent from each other, and the vacuum pump C120 is desirably high in the vacuum exhaust performance than the vacuum pump B109. The vacuum pump B109 and the vacuum pump C120 can also be made to be the same vacuum pump obtained by connecting the vacuum pumps to each other so as to be adjusted in a vacuum exhaust conductance or a pump performance and so as to make a difference in a vacuum exhaust speed therebetween.

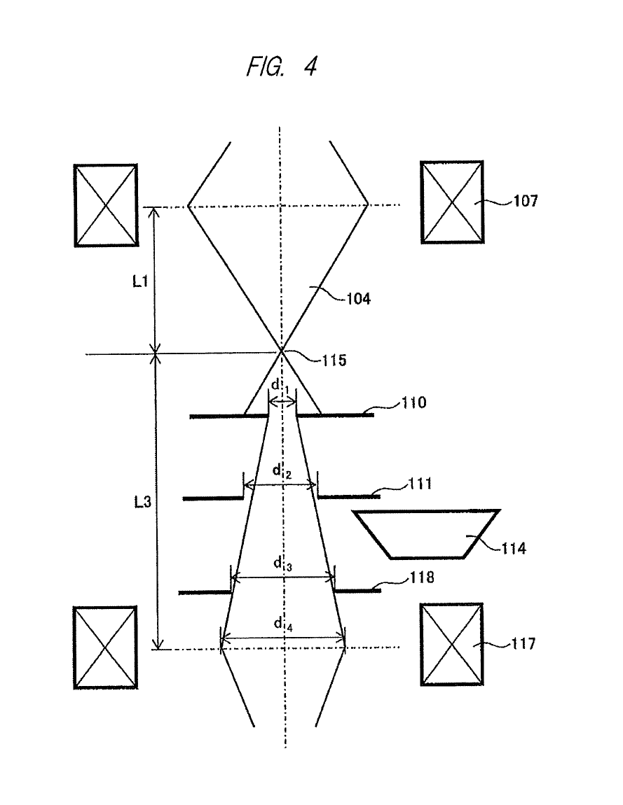

FIG. 4 is an enlarged view of the periphery of the objective final aperture 110 of FIG. 3. The increase in the amount of the charged particles which are applied on the object 113 increases a diameter of the charged particle beam with which the object 113 of the charged particle device 200 configured in FIG. 3 is irradiated because the diameter is influenced by a lens aberration generated by the condenser lens B117. In order to avoid this deterioration of the particle beam diameter, it is required to decrease a diameter “d₄” of the charged particle beam at the condenser lens B117 by arranging a distance “L3” between the crossover point A115 and the condenser lens B117 to be short as much as possible. The aperture for differential pumping B118 is desirably arranged to be closer to the objective final aperture 110 side than the condenser lens B117 in order to satisfy various optical conditions. In other words, the condenser lens B117 is provided to be closer to the object 113 side than the aperture for differential pumping B118.

In addition, in order to adjust an optical axis, the aperture for differential pumping B118 is desirably movable.

Note that the present invention is not limited to the above-described examples, and include various modified examples. For example, the above-described examples have been described in detail for easily understanding the present invention, and are not always limited to the one including all of the described components. Also, the configuration of one example can be partially replaced with the configuration of the other example, and the configuration of the other example can be added to the configuration of one example. Further, the configuration of the other example can be partially added to/eliminated from/replaced with the configuration of each example.

### SYMBOL EXPLANATION

101 emitter of the charged particle

102 electrode for the extractor voltage

103 electrode for the acceleration voltage

104 charged particle beam

105 vacuum chamber A

106 vacuum chamber B

107 condenser lens A

108 vacuum pump A

109 vacuum pump B

110 objective final aperture

111 aperture for differential pumping A

112 stage

113 object

114 valve

115 crossover point A

116 objective lens

117 condenser lens B

118 aperture for differential pumping B

119 crossover point B

120 vacuum pump C

121 vacuum chamber C

d₁ hole diameter of objective final aperture

d₂ hole diameter of aperture for differential pumping A

d₃ hole diameter of aperture for differential pumping B

d₄ diameter of charged particle beam on a lens main plane created by condenser lens B

L1 distance from a lens main plane created by condenser lens A and crossover point A

L2 distance from objective final aperture to aperture for differential pumping A

L3 distance from a crossover point A and a lens main plane created by condenser lens B

1. A charged particle beam device which detects a secondary particle received from a sample due to the irradiation with a charged particle beam and takes an image of the sample, comprising:
a lens barrel including therein:
an emitter of charged particle beam which generates the charged particle beam;
a condenser lens which can adjust a crossover point of the charged particle beam;
an objective final aperture which is arranged to be closer to the sample side than from the condenser lens and which is used while heated; and
an objective lens which is arranged to be closer to the sample side than the objective final aperture and which converges the charged particle beam on the sample; and
a sample chamber including therein a sample stage on which the sample is placed,
wherein the lens barrel includes therein a first space having a first degree of vacuum and a second space having a degree of vacuum higher than the first degree of vacuum,
the objective final aperture used while heated is arranged in the second space, and
the sample chamber can be atmospherically exposed while heating the objective final aperture.

2. The charged particle beam device according to claim 1,
wherein the first space and the second space are connected to each other by an aperture for differential pumping, and
the charged particle beam device includes a valve by which an opening of the aperture for differential pumping can be moved into either an opening state or a closing state, and
the objective final aperture is arranged to be closer to the emitter side of charged particle beam than the valve.

3. The charged particle beam device according to claim 1,
wherein the charged particle beam device includes a control unit which adjusts a position of the crossover point by controlling the condenser lens, and an amount of a beam current of the charged particle beam can be changed in accordance with the position of the crossover point.

4. The charged particle beam device according to claim 1,
wherein the first space and the second space are connected to each other by an aperture for differential pumping, and
the objective final aperture is arranged so that a distance L between the objective final aperture and the aperture for differential pumping is 20 mm or smaller.

5. The charged particle beam device according to claim 2,
wherein the aperture for differential pumping is arranged to be closer to the sample side than the objective final aperture, and
the valve is arranged to be closer to the sample side than the aperture for differential pumping.

6. The charged particle beam device according to claim 1,
wherein the first space and the second space are connected to each other by a first aperture for differential pumping, and
the charged particle beam device includes:
a second aperture for differential pumping arranged to be closer to the sample side than the first aperture for differential pumping; and
a second condenser lens arranged to be closer to the sample side than the second aperture for differential pumping.

7. The charged particle beam device according to claim 1,
wherein the emitter of the charged particle beam emits the charged particle beam by an effect of an electric field.
